(19) United States
(12) Patent Application Publication
(10) Pub. No.: US 2025/0087920 A1
(43) Pub. Date: Mar. 13, 2025

(54) TRUNK LINE OF WIRE HARNESS AND WIRE HARNESS

(71) Applicant: Yazaki Corporation, Tokyo (JP)

(72) Inventors: Yukinori YAMAMOTO, Shizuoka (JP); Yoshiaki ICHIKAWA, Shizuoka (JP); Tomoyuki MIYAKAWA, Canton, MI (US)

(73) Assignee: Yazaki Corporation, Tokyo (JP)

(21) Appl. No.: 18/958,057

(22) Filed: Nov. 25, 2024

Related U.S. Application Data
(63) Continuation of application No. PCT/JP2023/038193, filed on Oct. 23, 2023.

(30) Foreign Application Priority Data
Oct. 28, 2022 (JP) 2022-173132

(51) Int. Cl. H01R 12/81; B60R 16/02

(52) U.S. Cl. CPC H01R 12/81; B60R 16/0215

(57) ABSTRACT

A trunk line of a wire harness includes a flexible printed circuit having a linear shape, and a plurality of connectors, one or more of the plurality of connectors being installed at each of a first side end portion and a second side end portion of the flexible printed circuit. Each of the plurality of connectors has a structure of being engaged with an external connector attached to an external electric wire.

### CROSS-REFERENCE TO RELATED APPLICATIONS

The present application is a continuation of International Application No. PCT/JP2023/038193, filed on Oct. 23, 2023, and based on and claims the benefit of priority from the prior Japanese Patent Application No. 2022-173132, filed on Oct. 28, 2022, the entire contents of which are incorporated by reference herein.

### TECHNICAL FIELD

The present disclosure relates to a trunk line of a wire harness and a wire harness.

### BACKGROUND

Hitherto, there has been provided a wire harness installed within a vehicle to supply electric power or transmit a communication signal. JP2002-203431 A discloses a technique relating to a flat harness obtained by combining a flexible flat cable (FFC) and a flexible printed circuit (FPC) with each other.

### SUMMARY OF THE INVENTION

The flat harness disclosed in JP2002-203431 A is obtained by combining the two types of wiring lines including the FFC and the FPC, and thus can be used separately for a high-current circuit and a low-current circuit. However, it is difficult to increase the size due to its structure, and expandability is low because the FFC and the FPC are integrated with each other.

It is an object of the disclosure to provide a trunk line of a wire harness and a wire harness that can be increased in size and improve expandability.

A trunk line of a wire harness according to an aspect of the present disclosure includes a flexible printed circuit having a linear shape, and a plurality of connectors, one or more of the plurality of connectors being installed at each of both side end portions of the flexible printed circuit, wherein each of the plurality of connectors has a structure of being engaged with an external connector attached to a branch line configured by an external electric wire.

A wire harness according to another aspect of the present disclosure includes a trunk line, and a plurality of branch lines being electrically connected to the trunk line, wherein the trunk line is the above-mentioned trunk line of the wire harness, and each of the plurality of branch lines is configured by the electric wire including one end portion to which the external connector to be engaged with the connector of the trunk line is attached.

### BRIEF DESCRIPTION OF DRAWINGS

FIG. 1 is a diagram illustrating an installation example of a wire harness according to a first embodiment.

FIG. 2 is a diagram illustrating a configuration example of the wire harness according to the first embodiment.

FIG. 3 is a diagram illustrating a configuration example of a trunk line of the wire harness according to a first embodiment.

FIG. 4 is a diagram illustrating a configuration example of a wire harness according to a second embodiment.

FIG. 5 is a diagram illustrating a configuration example of a wire harness according to a third embodiment.

### DETAILED DESCRIPTION OF THE INVENTION

With reference to the drawings, a trunk line of a wire harness and a wire harness according to each embodiment is described in detail. Note that the dimensional ratios in the drawings are exaggerated for explanatory purposes, and may differ from the actual ratios.

### First Embodiment

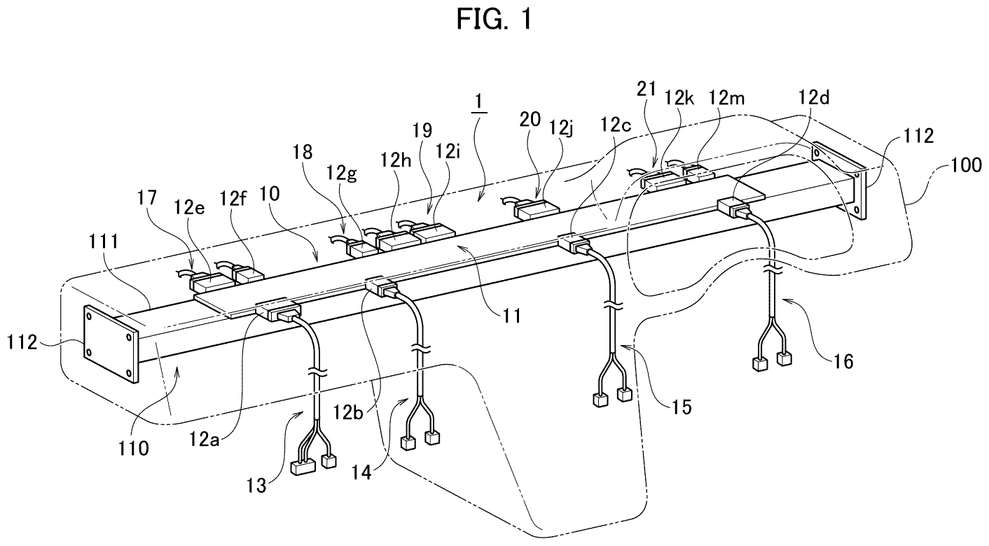

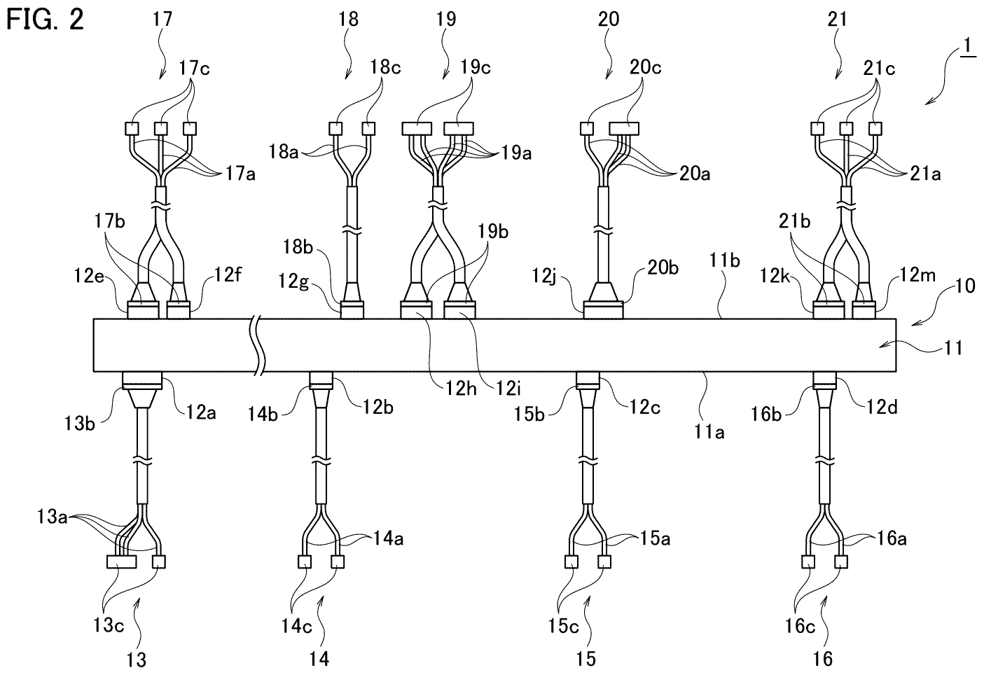

FIG. 1 is a perspective view schematically illustrating an arrangement example of a wire harness 1 according to a first embodiment. FIG. 2 is a plan view schematically illustrating a configuration example of the wire harness 1. For example, the wire harness 1 is a wiring line member that is routed within a vehicle, such as an automobile, to electrically connect a plurality of on-board devices to each other.

In the present embodiment, as one example, the wire harness 1 is attached to a cross-car beam 111 installed inside an instrument panel 100 of an automobile. The instrument panel 100 is an interior panel that is arranged at a front of a vehicle cabin and extends along a width direction of a vehicle to face a driver's seat and a passenger's seat. Note that, in FIG. 1, the instrument panel 100 is indicated by the two-dot chain line. The cross-car beam 111 is a reinforcement member that is configured by a metal hollow pipe and is installed along a width direction of a vehicle. The flanges 112 are respectively joined to both ends of the cross-car beam 111. One of the flanges 112 is fastened to a left front pillar of an automobile by a bolt, and the other of the flanges 112 is fastened to a right front pillar by a bolt. Note that, in FIG. 1, the front pillars are omitted in illustration.

The wire harness 1 includes a trunk line 10 and a plurality of branch lines such as a first branch line 13.

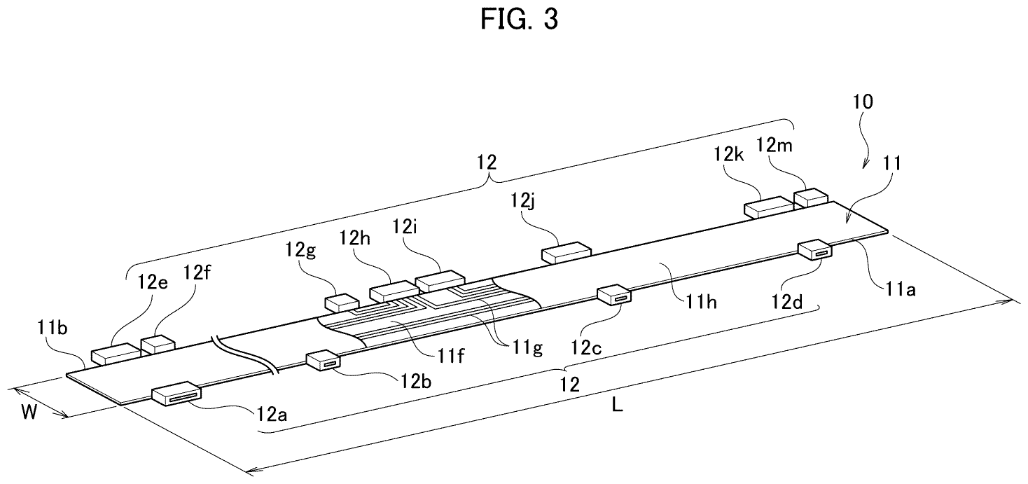

FIG. 3 is a perspective view schematically illustrating a configuration example of the trunk line 10. The trunk line 10 includes an FPC 11 and a plurality of connectors 12. Herein, FPC is an abbreviation of Flexible Printed Circuit.

The FPC 11 is a thin printed circuit excellent in flexibility. The FPC 11 includes a base film 11f, a pattern layer 11g, and a cover lay 11h. The base film 11f is a base material that is excellent in flexibility and defines a shape of the entire FPC 11. For example, the base film 11f is formed of a polyimide resin excellent in heat resistance. The pattern layer 11g is laminated on a part of at least one main surface of the base film 11f, and configures a plurality of conductive circuits. For example, the pattern layer 11g is formed of a copper foil. The cover lay 11h is a protective layer that is laminated on the entire surface of the base film 11f, that is, the base film 11f or the pattern layer 11g via an adhesive, which is omitted in illustration, and protects the pattern layer 11g and the like.

Further, the FPC 11, as a whole, has a linear shape that defines a length L, a width W, and a planar shape. Herein, the length L corresponds to a length of the FPC 11 in a longitudinal direction. The FPC 11 includes two side end portions, specifically, a first side end portion 11a and a second side end portion 11b, each of which extends along the longitudinal direction. The second side end portion 11b is positioned on a side opposite to the first side end portion 11a in the width direction. The length L falls within a range from 500 mm to 1,500 mm. The width W falls within a range from 40 mm to 100 mm.

One or more of the plurality of connectors 12 are installed at each of the first side end portion 11a and the second side end portion 11b of the FPC 11. As one example, the trunk line 10 includes twelve connectors 12. A first connector 12a, a second connector 12b, a third connector 12c, and a fourth connector 12d are installed at an interval therebetween on the first side end portion 11a. Meanwhile, a fifth connector 12e, a sixth connector 12f, a seventh connector 12g, an eighth connector 12h, a ninth connector 12i, a tenth connector 12j, an eleventh connector 12k, and a twelfth connector 12m are installed at an interval therebetween on the second side end portion 11b. Each of the connectors 12 has a structure of being engaged with any one of external connectors respectively attached to the plurality of branch lines. Note that specifications, such as the number of poles, of each of the connectors 12 or arrangement of each of the connectors 12 in the FPC 11 may be changed as appropriate in accordance with an attachment position of the wire harness 1 in a vehicle or the like.

Further, each of the connectors 12 is electrically connected to the pattern layer 11g of the FPC 11. Each of the plurality of conductive circuits configured by the pattern layer 11g may function as any one of a signal circuit, a signal GND circuit, a power-dedicated earth circuit, and the like. The signal circuit transmits a communication signal between on-board devices. The signal GND circuit electrically connects on-board devices along with the signal circuit, and aligns a reference potential for a circuit operation between the on-board devices. The power-dedicated earth circuit grounds a power source system of an on-board device.

Each of the plurality of branch lines is a type of an electric wire including one end connected to any one of the plurality of connectors 12 provided to the trunk line 10 and the other end connected to each electronic device or the like. In the present embodiment, as one example, there are nine branch lines including the first branch line 13, a second branch line 14, a third branch line 15, a fourth branch line 16, a fifth branch line 17, a sixth branch line 18, a seventh branch line 19, an eighth branch line 20, and a ninth branch line 21.

Each of the branch lines includes an external connector that is engaged with any one of the connectors 12 of the trunk line 10, a branch end portion that is connected to each electronic device or the like, and an electric wire that connects the external connector and the branch end portion to each other. The electric wire in the present embodiment is a linear and conductive member formed of metal, and is not an FPC. Further, the branch end portion in the present embodiment may be selected in accordance with a type and the number of electric wires, and may be a joint connector such as a multi-core connector or a crimped terminal. Further, the branch end portion in the present embodiment may be a junction block, or may be a relay block or the like.

For example, the first branch line 13 includes a first electric wire 13a, a first external connector 13b, and a first branch end portion 13c. The plurality of first electric wires 13a are provided in accordance with the two first branch end portion 13 having different shapes from each other. Those first electric wires 13a may be any one of a power wire, a signal wire, a power-dedicated earth wire, and the like. Note that the plurality of first electric wires 13a may be protected by an exterior protection member configured by a vinyl tube, an adhesive tape, or the like. Alternatively, the plurality of first electric wires 13a may be bundled by a cable tie, which is omitted in illustration. The first external connector 13b has a structure of being engaged with the first connector 12a of the trunk line 10.

Meanwhile, for example, similarly to the configuration of the first branch line 13, the eighth branch line 20 that is connected to the trunk line 10 via the tenth connector 12j provided to the second side end portion 11b may also include an eighth electric wire 20a, an eighth external connector 20b, and an eighth branch portion 20c. The eighth external connector 20b has a structure of being engaged with the tenth connector 12j of the trunk line 10.

Further, for example, the configuration of each of the branch lines is not limited to the example of the first branch line 13, and may be, for example, a configuration similar to the second branch line 14, the fifth branch line 17, or the seventh branch line 19.

The second branch line 14 includes a second electric wire 14a, a second external connector 14b, and a second branch end portion 14c. Each of the two second branch end portions 14c may include a simple configuration as compared to the first branch end portion 13c. The second external connector 14b has a structure of being engaged with the second connector 12b of the trunk line 10. However, the engagement structure between the second connector 12b and the second external connector 14b may be smaller in size than the engagement structure between the first connector 12a and the first external connector 13b.

Meanwhile, for example, similarly to the configuration of the second branch line 14, the third branch line 15 that is connected to the trunk line 10 via the third connector 12c may also include a third electric wire 15a, a third external connector 15b, and a third branch end portion 15c. The third external connector 15b has a structure of being engaged with the third connector 12c of the trunk line 10. Further, for example, similarly to the configuration of the second branch line 14, the fourth branch line 16 may also include a fourth electric wire 16a, a fourth external connector 16b engaged with the fourth connector 12d of the trunk line 10, and a fourth branch end portion 16c. Further, similarly to the configuration of the second branch line 14, the sixth branch line 18 may also include a sixth electric wire 18a, a sixth external connector 18b engaged with the seventh connector 12g of the trunk line 10, and a sixth branch end portion 18c.

The fifth branch line 17 includes a fifth electric wire 17a, a fifth external connector 17b, and a fifth branch end portion 17c. In the fifth branch line 17, the number of fifth branch end portions 17c is greater than the number of first branch end portions 13c in the first branch line 13. Further, in the fifth branch line 17, the number of fifth external connectors 17b is greater than the number of first external connectors 13b in the first branch line 13. In the example of the fifth branch line 17, the two fifth external connectors 17b are present. In this case, one of the fifth external connectors 17b has a structure of being engaged with the fifth connector 12e, and the other of the fifth external connectors 17b has a structure of being engaged with the sixth connector 12f adjacent to the fifth connector 12e.

Meanwhile, for example, similarly to the configuration of the fifth branch line 17, the ninth branch line 21 that is connected to the trunk line 10 via the eleventh connector 12k and the twelfth connector 12m may also include a ninth electric wire 21a, two ninth external connectors 21b, and three ninth branch end portions 21c. In this case, one of the ninth external connectors 21b has a structure of being engaged with the eleventh connector 12k, and the other of the ninth external connectors 21b has a structure of being engaged with the twelfth connector 12m adjacent to the eleventh connector 12k.

The seventh branch line 19 includes a seventh electric wire 19a, a seventh external connector 19b, and a seventh branch end portion 19c. In the seventh branch line 19, the number of seventh electric wires 19a is greater than the number of first electric wires 13a in the first branch line 13. Further, in the seventh branch line 19, the number of seventh external connectors 19b is greater than the number of first external connectors 13b in the first branch line 13. In the example of the seventh branch line 19, the two seventh external connectors 19b are present. In this case, one of the seventh external connectors 19b has a structure of being engaged with the eighth connector 12h, and the other of the seventh external connectors 19b has a structure of being engaged with the ninth connector 12i adjacent to the eighth connector 12h.

Herein, the first branch line 13, the second branch line 14, the third branch line 15, or the fourth branch line 16, which is routed from the first side end portion 11a of the FPC 11 to a driver's seat side or a passenger's seat side, may be connected to electric equipment, such as a meter panel and an air-conditioning device, that is attached to the instrument panel 100. Meanwhile, the fifth branch line 17, the sixth branch line 18, the seventh branch line 19, the eighth branch line 20, or the ninth branch line 21, which is routed from the second side end portion 11b of the FPC 11 to an engine room side may be connected to a main battery, various control boxes, or the like.

Next, effects of the trunk line 10 of the wire harness 1 and the wire harness 1 including the trunk line 10 are described.

The trunk line 10 of the wire harness 1 according to the present embodiment includes the FPC 11 having a linear shape and the plurality of connectors 12, one or more of the plurality of connectors 12 being installed at each of the first side end portion 11a and the second side end portion 11b that are both the side end portions of the FPC 11. Each of the plurality of connectors 12 has a structure of being engaged with the external connector attached to the external electric wire.

Herein, the external electric wire corresponds to the above-mentioned branch line, such as the first branch line 13 and the like, in the wire harness 1. The external connector corresponds to the first external connector 13b and the like described above, which are attached to the respective branch line.

Further, the wire harness 1 according to the present embodiment includes the trunk line 10, the plurality of branch lines, such as the first branch line 13 and the like, which are electrically connected to the trunk line 10. Each of the plurality of branch lines is configured by the electric wire including one end portion to which the external connector to be engaged with the connector 12 of the trunk line 10 is attached.

First, in the present embodiment, the trunk line 10 of the wire harness 1 is configured by the FPC 11 instead of an electric wire. Therefore, the trunk line 10 configured by the FPC 11 is reduced in weight as compared to a trunk line obtained by bundling various types of general electric wires. Herein, as described above, when the wire harness 1 is installed within a vehicle, it is assumed that the length L of the trunk line 10 is approximately 1,000 mm. Herein, when the trunk line having such a length is configured entirely by electric wires, a weight of the trunk line itself, consequently, that of a wire harness as a whole is significantly increased. In contrast, according to the trunk line 10 or the wire harness 1, the trunk line 10 or the wire harness 1 as a whole is reduced in weight to a higher extent as the length L is set longer, and hence a size increase of the wire harness 1 can easily be suppressed while suppressing a weight increase.

For example, as described above, it is assumed that the wire harness 1 is attached to the inside of the instrument panel 100. In general, a large-size wire harness, which is attached within the instrument panel 100 as described above, includes a large number of branch lines corresponding to various devices such as a meter, an air-conditioning device, and an audio device, and is heavier than wire harnesses attached to other parts of a vehicle. Further, in such a large-size wire harness, some branch lines may include connectors such as a joint connectors, which are not actually used. In contrast, the wire harness 1 according to the present embodiment enables connection of a suitable branch line including a required connector only, and hence it is possible to eliminate a branch line including preparatory connectors, which are not actually used. Therefore, according to the wire harness 1 according to the present embodiment, a weight loss by approximately 30% can be achieved as compared to a general wire harness including a trunk line configured by bundling various electric wires.

Further, in general, in a large-size wire harness including a trunk line configured by bundling various electric wires, due to its structure, it may be difficult to adopt, as a branch line, a thin electric wire having a permissive current value of approximately a few milliamperes. In contrast, in the present embodiment, the trunk line 10 has a small thickness as a whole, and is configured by the FPC 11 including the fine pattern layer 11g, and hence it is easy to adopt a structure of connecting a branch line formed of an electric wire defined with the above-mentioned current range.

Further, in general, a wire harness including a trunk line configured by bundling various electric wires is manufactured manually by a worker. In view of this, the FPC 11 can be manufactured through automation, and hence the number of steps of manufacturing the trunk line 10, consequently, the number of steps of manufacturing the wire harness 1 can also be reduced by configuring the trunk line 10 by the FPC 11.

Further, in the present embodiment, an external electric wire, that is, a branch line is connected to the trunk line 10 via the connector 12, and hence is attached and removed freely with respect to the trunk line 10. Therefore, in the final step of manufacturing the wire harness 1, a worker is only required to connect a plurality of branch lines that are prepared in advance to the trunk line 10. For example, a worker can assemble the wire harness 1 as a whole by first attaching, to the cross-car beam 111, the trunk line 10 before connection to branch lines, and then connecting the respective branch lines to the trunk line 10. In other words, this may contribute to reduction of the number of steps of designing the wire harness 1 or facilitation of a manufacturing work of a vehicle adopting the wire harness 1. Further, according to the trunk line 10 and the wire harness 1, a branch line can be replaced with respect to one trunk line 10. Therefore, when one branch line is damaged, only the damaged branch line can easily be replaced. Meanwhile, the trunk line 10 is commonly shared, and only a desired branch line is changed as appropriate. With this, various wire harnesses 1 having different types or lengths of respective branch lines being adopted can easily be configured. Further, it is possible to provide a so-called add-on expansion function that allows a new function, which is not originally set to the wire harness 1 at the time of assembling to a vehicle, to be added after the assembly. Note that the trunk line 10 configured by the FPC 11 may be attached to the cross-car beam 111 via a protector for covering and protecting the entire trunk line 10.

Further, a branch line can freely be attached and removed with respect to the trunk line 10, and hence the following advantages are provided. Firstly, according to the wire harness 1, the trunk line 10 and the plurality of branch lines may be managed under respective original item numbers. For example, as a comparative example, there is assumed a case where a plurality of general wire harnesses that are different from each other only in a length of a certain branch line are provided. In this case, the plurality of wire harnesses 1 are respectively denoted with different item numbers, and are managed. In contrast, according to the wire harness 1, the branch lines having different lengths are respectively denoted with item numbers, and the trunk line 10 that is commonly shared is denoted with one item number and is managed. Therefore, it is possible to easily increase the variations of branch line changes and contribute to the simplification of labor management associated with changes in the configuration of the wire harness 1. Secondly, in general, it is also difficult to transport a large-size wire harness including a trunk line configured by bundling various electric wires, due to its weight. In contrast, according to the wire harness 1, the trunk line 10 and the branch line can be transported separately, and hence there are advantages such as shortening the manufacturing days of the wire harness 1 itself or a vehicle using the wire harness 1, and reducing the limitations on manufacturing locations. Thirdly, according to the wire harness 1, the branch line can be manufactured independently from the trunk line 10, and hence nay be manufactured by an automated machine rather than manual work by a worker. In other words, according to the wire harness 1, both the trunk line 10 configured by the FPC 11 and the branch line configured by the electric wire, in other words, the wire harness 1 as a whole can be manufactured by an automated machine, which is advantageous for reducing costs.

Further, in the present embodiment, the FPC 11 has a linear shape, and hence, the trunk line 10 and the wire harness 1 are easily adopted to various attachment parts within a vehicle. Note that, even when the FPC 11 has an elongated shape having the length L of approximately 1,000 mm, the FPC 11 having a linear shape can further facilitate manufacturing of the FPC 11 in an FPC manufacturing device.

Further, in the present embodiment, one or more of the plurality of connectors 12 are installed at each of the first side end portion 11a and the second side end portion 11b, and hence the trunk line 10 can connect the respective branch lines to each other from the opposite sides. Therefore, as described above, when the wire harness 1 is installed within a vehicle, the trunk line 10 enables an increase in the number of set branch lines to be connected and an increase in variation of the configurations of the wire harness 1.

Further, in the present embodiment, each of the plurality of connectors 12 has a structure of being engaged with an external connector attached to an external electric wire. In other words, an external electric wire, that is, the branch line itself has a structure similar to that of a branch line of a general wire harness, and hence the wire harness 1 can easily be used in place of a general wire harness configured entirely by electric wires.

As described above, according to the present embodiment, it is possible to provide the trunk line 10 of the wire harness 1 and the wire harness 1 that can be increased in size and improve expandability.

Further, in the trunk line 10, the length L of the FPC 11 may fall within a range from 500 mm to 1,500 mm. The width W of the FPC 11 may fall within a range from 40 mm to 100 mm.

The trunk line 10 is suitable particularly in a case where the wire harness 1 is installed within a vehicle as exemplified above. Further, when the length L and the width W of the FPC 11 are set within the above-mentioned ranges, the wire harness 1 including the trunk line 10 can be used more widely in place of a general wire harness configured entirely by electric wires.

### Second Embodiment

In the wire harness 1 according to the first embodiment, only the trunk line 10 configured by the FPC 11 is adopted as a trunk line. In view of this, in a wire harness 2 according to a second embodiment, an auxiliary wiring line 22 capable of functioning as a part of the trunk line is further adopted in addition to the FPC 11.

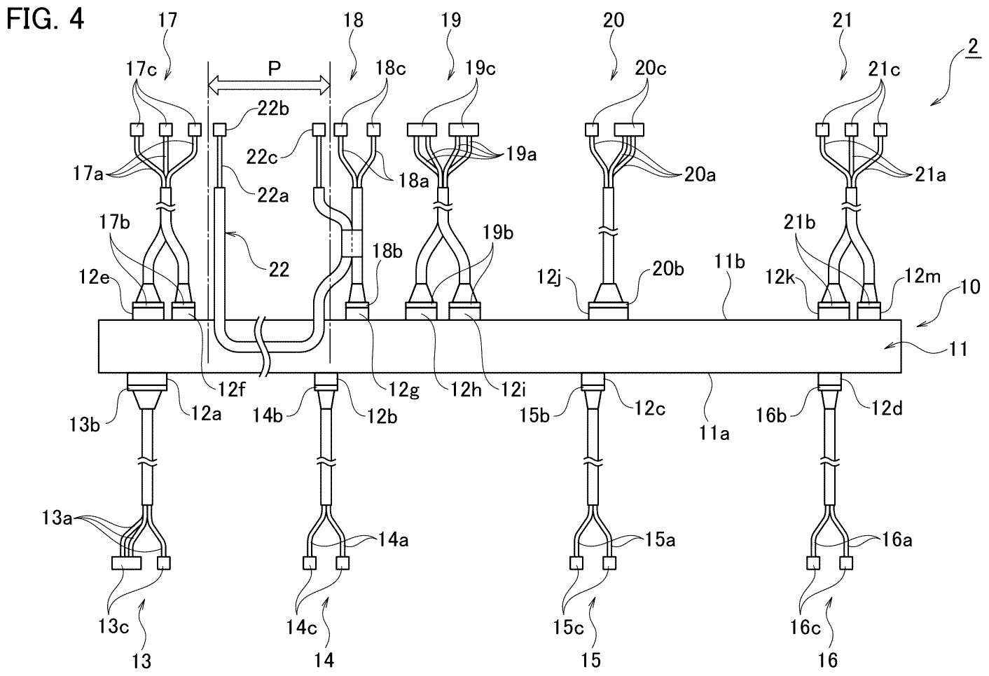

FIG. 4 is a plan view schematically illustrating a configuration example of the wire harness 2. FIG. 4 is illustrated so as to correspond to FIG. 2 illustrating the configuration example of the wire harness 1 according to the first embodiment. Hereinafter, among the constituent elements of the wire harness 2, the same constituent elements as those of the wire harness 1 are denoted with the same reference symbols, and description therefor is omitted.

The wire harness 2 includes the auxiliary wiring line 22 configured by an electric wire. In the wire harness 2, a position at which the auxiliary wiring line 22 is arranged is not particularly limited, and is arranged between the fifth branch line 17 and the sixth branch line 18 in the present embodiment, as one example. The auxiliary wiring line 22 includes one auxiliary electric wire 22a, a first wiring line terminal 22b attached to one end of the auxiliary electric wire 22a, and a second wiring line terminal 22c attached to the other end of the auxiliary electric wire 22a. For example, the auxiliary wiring line 22 may be bundled together with another adjacent branch line, such as the sixth branch line 18. Herein, a part of the auxiliary wiring line 22 is arranged along at least a part of the trunk line 10 in the longitudinal direction. In the example illustrated in FIG. 4, in a parallel section P, the trunk line 10 and a part of the auxiliary wiring line 22 are arranged in parallel to each other. In other words, as well as the trunk line 10, a part of the auxiliary wiring line 22 in the parallel section P may be regarded as a part of the trunk line in the wire harness 2.

In this manner, the wire harness 2 may include the auxiliary wiring line 22 configured by an electric wire. Further, a part of the auxiliary wiring line 22 may be arranged along at least a part of the trunk line 10 in the longitudinal direction.

Herein, the trunk line 10 is configured by the FPC 11, but, when attempting to conduct a relatively large current from one branch line to another branch line via the trunk line 10, it is conceivable that conduction might be practically difficult in a conductor circuit included in the pattern layer 11g of the FPC 11. In view of this, according to the wire harness 2, when a need arises to pass such a large current through the trunk line, it can be addressed by routing the current through the auxiliary wiring line 22 configured by an electric wire, instead of passing it through the trunk line 10 configured by the FPC 11. In this state, as the auxiliary electric wire 22a, an auxiliary electric wire having a suitable wire width for conducting a desired current is selected in advance.

### Third Embodiment

In the wire harness 2 according to the second embodiment, a part of the auxiliary wiring line 22 that can further function as a trunk line is arranged in parallel to the trunk line 10 configured by the FPC 11. In view of this, in a wire harness 3 according to a third embodiment, an auxiliary trunk line 40 being a trunk line connected to an FPC 31 in series is adopted.

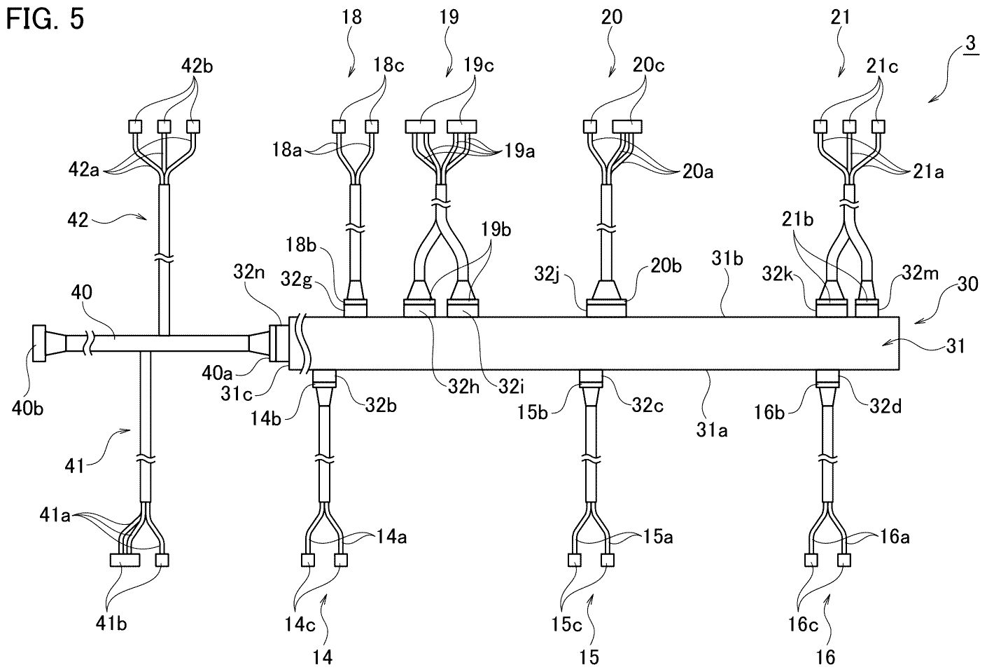

FIG. 5 is a plan view schematically illustrating a configuration example of the wire harness 3. FIG. 5 is illustrated so as to correspond to FIG. 2 illustrating the configuration example of the wire harness 1 according to the first embodiment. Hereinafter, among the constituent elements of the wire harness 3, the same constituent elements as those of the wire harness 1 are denoted with the same reference symbols, and description therefor is omitted.

First, the wire harness 3 includes a trunk line 30 in place of the trunk line 10 of the wire harness 1. The trunk line 30 includes the FPC 31, a second connector 32b, a third connector 32c, a fourth connector 32d, a seventh connector 32g, an eighth connector 32h, a ninth connector 32i, a tenth connector 32j, an eleventh connector 32k, and a twelfth connector 32m. The FPC 31 has substantially the same structure as the FPC 11 of the trunk line 10, but the region of the trunk line 10 where the first branch line 13 and the fifth branch line 17 are connected to each other is replaced with the auxiliary trunk line 40 in the present embodiment. Note that the above-mentioned connectors of the trunk line 30 respectively correspond to the connectors of the trunk line 10, which are denoted with the same names.

Further, similarly to the FPC 11, the FPC 31 includes a first side end portion 31a and a second side end portion 31b, and a distal end portion 31c along the width W vertical to both the first side end portion 31a and the second side end portion 31b is defined in the present embodiment. At the distal end portion 31c, an auxiliary connector 32n is installed. Similarly to the second connector 32b and the like, the auxiliary connector 32n is also electrically connected to the pattern layer included in the FPC 31, which is omitted in illustration.

Further, the wire harness 3 includes the auxiliary trunk line 40 configured by an electric wire. An auxiliary external connector 40a connected to the auxiliary connector 32n is attached to one end of the auxiliary trunk line 40. In other words, the auxiliary connector 32n of the FPC 31 has a structure of being engaged with the auxiliary external connector 40a. Meanwhile, at the other end of the auxiliary trunk line 40, an end connector 40b that can be connected to other electric devices or the like may be attached.

At least one branch line branches from the auxiliary trunk line 40. In the example illustrated in FIG. 4, a tenth branch line 41 in place of the first branch line 13 of the trunk line 10 and an eleventh branch line 42 in place of the fifth branch line 17 of the trunk line 10 branch from the auxiliary trunk line 40. The tenth branch line 41 includes a tenth electric wire 41a and a tenth branch end portion 41b. The eleventh branch line 42 includes an eleventh electric wire 42a and an eleventh branch end portion 42b.

In this manner, the wire harness 3 may include the auxiliary trunk line 40 configured by an electric wire. The trunk line 30 may include the auxiliary connector 32n installed at the one distal end portion 31c of the FPC 31. The auxiliary connector 32n may have a structure of being engaged with the auxiliary external connector 40a attached to the auxiliary trunk line 40.

In the wire harness 3, not all the trunk lines are configured by FPCs, but a trunk line in which an FPC part corresponding to the FPC 31 and an electric wire part corresponding to the auxiliary trunk line 40 are continuous with each other in series is provided. For example, the auxiliary trunk line 40 described above may be used as a circuit for an air bag or an antenna. In this state, the auxiliary trunk line 40 may include an important circuit such as a power line or a conditional circuit. Therefore, according to the wire harness 3, expandability can further be improved.

Note that, in the description given above, a case where the wire harness 1 is attached to the inside of the instrument panel 100 of the automobile is given as an example. However, the attachment position of the wire harness 1 is not limited thereto, and may be, for example, under a floor or inside a roof of an automobile.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A trunk line of a wire harness, comprising:
a flexible printed circuit having a linear shape; and
a plurality of connectors, one or more of the plurality of connectors being installed at each of both side end portions of the flexible printed circuit, wherein
each of the plurality of connectors has a structure of being engaged with an external connector attached to an external electric wire.

2. The trunk line of a wire harness according to claim 1, wherein
a length of the flexible printed circuit falls within a range from 500 mm to 1,500 mm, and
a width of the flexible printed circuit falls within a range from 40 mm to 100 mm.

3. A wire harness, comprising:
a trunk line; and
a plurality of branch lines being electrically connected to the trunk line, wherein
the trunk line includes a flexible printed circuit having a linear shape; and
a plurality of connectors, one or more of the plurality of connectors being installed at each of both side end portions of the flexible printed circuit,
each of the plurality of connectors has a structure of being engaged with an external connector attached to an external electric wire, and
each of the plurality of branch lines is configured by the electric wire including one end portion to which the external connector to be engaged with the connector of the trunk line is attached.

4. The wire harness according to claim 3, further comprising:
an auxiliary wiring line configured by an electric wire, wherein
a part of the auxiliary wiring line is arranged along at least a part of the trunk line in a longitudinal direction.

5. The wire harness according to claim 3, further comprising:
an auxiliary trunk line configured by an electric wire, wherein
the trunk line includes an auxiliary connecter being installed at one distal end portion of the flexible printed circuit, and
the auxiliary connector has a structure of being engaged with an auxiliary external connector attached to the auxiliary trunk line.

6. The wire harness according to claim 3, wherein
a length of the flexible printed circuit falls within a range from 500 mm to 1,500 mm, and
a width of the flexible printed circuit falls within a range from 40 mm to 100 mm.
